(19) United States
(12) Patent Application Publication
(10) Pub. No.: US 2019/0181108 A1
(43) Pub. Date: Jun. 13, 2019

(54) Semiconductor Package Structure and Semiconductor Package Structure Fabricating Method

(71) Applicant: Huawei Technologies Co., Ltd., Shenzhen (CN)

(72) Inventors: Cheng Ting Chen, Hsinchu (TW); Sheng Chieh Chang, Hsinchu (TW); Yu Xia, Shenzhen (CN)

(21) Appl. No.: 16/279,435

(22) Filed: Feb. 19, 2019

Related U.S. Application Data
(63) Continuation of application No. PCT/CN2017/098290, filed on Aug. 21, 2017.

(30) Foreign Application Priority Data
Aug. 19, 2016 (CN) 201610697554.0

(51) Int. Cl. H01L 23/00

(52) U.S. Cl. CPC H01L 24/05; H01L 24/03; H01L 2224/0401; H01L 2224/0239; H01L 2924/37001; H01L 2224/05155; H01L 2224/05139; H01L 2224/05111; H01L 2224/05147

(57) ABSTRACT

A semiconductor package structure includes a connection pad disposed on a semiconductor component. A protective layer includes a first non-conductive material, a first part, and a second part. The first part covers the semiconductor component except the connection pad, a surface of the first part is at a first height, the second part covers a periphery of the connection pad, a surface of the second part is at a second height, the first height is less than the second height, a middle part of the connection pad is exposed, and the first part and the second part are connected at an edge of the connection pad.

### CROSS-REFERENCE TO RELATED APPLICATIONS

This application is a continuation of International Patent Application No. PCT/CN2017/098290 filed on Aug. 21, 2017, which claims priority to Chinese Patent Application No. 201610697554.0 filed on Aug. 19, 2016. The disclosures of the aforementioned applications are hereby incorporated by reference in their entireties.

### TECHNICAL FIELD

The present disclosure relates to the semiconductor field, and in particular, to a semiconductor package structure and a semiconductor package structure fabricating method.

### BACKGROUND

In semiconductor chip fabricating technologies, wafer level packaging means that all or most packaging test procedures are directly performed on a wafer before a wafer component is cut to fabricate individual components. Compared with a conventional procedure in which a wafer is first cut and then a packaging test is performed on an individual bare die obtained after the cutting, the wafer level packaging does not need any intermediate layer, filler, or lead frame and omits fabricating processes such as die bonding and wire bonding such that material and labor costs can be greatly reduced. In addition, in the wafer level packaging, redistribution and bumping technologies are usually used as a wire-winding means for input/output (I/O) ports. Therefore, the wafer level packaging has advantages of a smaller package size and better electrical performance. However, in a wafer level packaging technology, a conducting wire is prone to break off, and a yield rate and reliability of a fabricated chip need to be improved.

### SUMMARY

Embodiments of the present disclosure provide a semiconductor package structure and a semiconductor package structure fabricating method. The semiconductor package structure has a higher yield rate and better reliability, and signals transmitted using the semiconductor package structure are also more consistent.

According to a first aspect, an embodiment of the present disclosure provides a semiconductor package structure, including a semiconductor component, a connection pad, disposed on the semiconductor component, a protective layer, including a first non-conductive material, a first part, and a second part, where the first part covers the semiconductor component except the connection pad, a surface of the first part is at a first height, the second part covers a periphery of the connection pad, a surface of the second part is at a second height, the first height is less than the second height, a middle part of the connection pad is exposed, the middle part includes a part on the connection pad except the periphery, and the first part and the second part are connected at an edge of the connection pad, a flat layer, including a second non-conductive material and covering the first part, where a surface of the flat layer is at the second height, an under bump metallization layer, including a first metallic material and covering the flat layer, the second part, and the middle part, and a rewiring layer, including a second metallic material and covering the under bump metallization layer.

The surface of the flat layer is flush with the surface of the second part. The flat layer makes up a height difference between the first part and the second part of the protective layer such that the under bump metallization layer can cover a smoother surface, and a risk that the under bump metallization layer and the rewiring layer covering the under bump metallization layer distort, fracture, and peel off at an unsmooth part is reduced.

In a first possible implementation of the first aspect, the second non-conductive material includes silicon oxide. Compared with an organic material such as polyimide, using the silicon oxide to fabricate the flat layer can lead to higher smoothness precision in order to further reduce a risk that the under bump metallization layer and the rewiring layer covering the under bump metallization layer distort, fracture, and peel off. This helps improve a yield rate and reliability of a plurality of rewiring layers. In addition, the rewiring layer becomes more even because of improvement in flatness, and signals transmitted using the rewiring layer are also more consistent.

With reference to the first aspect or the first possible implementation of the first aspect, in a second possible implementation, the silicon oxide includes silicon dioxide.

With reference to any one of the first aspect, or the first and the second possible implementations of the first aspect, in a third possible implementation, the first non-conductive material includes silicon nitride.

With reference to any one of the first aspect, or the first to the third possible implementations of the first aspect, in a fourth possible implementation, the first metallic material includes at least one of copper, nickel, silver, or tin.

With reference to any one of the first aspect, or the first to the fourth possible implementations of the first aspect, in a fifth possible implementation, the second metallic material includes at least one of copper or aluminum.

According to a second aspect, an embodiment of the present disclosure provides a semiconductor package structure fabricating method, including fabricating a semiconductor component, disposing a connection pad on the semiconductor component, fabricating a protective layer using a first non-conductive material, where the protective layer includes a first part and a second part, and the fabricating a protective layer includes covering the semiconductor component except the connection pad with the first part such that a surface of the first part is at a first height, covering a periphery of the connection pad with the second part such that a surface of the second part is at a second height, where the first height is less than the second height, and exposing a middle part of the connection pad, where the middle part includes a part on the connection pad except the periphery, and the first part and the second part are connected at an edge of the connection pad, fabricating a flat layer using a second non-conductive material, where the fabricating a flat layer includes covering the first part with the flat layer such that a surface of the flat layer is at the second height, fabricating an under bump metallization layer using a first metallic material, and covering the flat layer, the second part, and the middle part with the under bump metallization layer, and fabricating a rewiring layer using a second metallic material, and covering the under bump metallization layer with the rewiring layer.

The flat layer makes up a height difference between the first part and the second part of the protective layer such that the under bump metallization layer can cover a smoother surface, and a risk that the under bump metallization layer and the rewiring layer covering the under bump metallization layer distort, fracture, and peel off at an unsmooth part is reduced.

In a first possible implementation of the second aspect, the covering the first part with the flat layer such that a surface of the flat layer is at the second height includes covering the protective layer and the middle part with a second non-conductive material using a chemical vapor deposition (CVD) process, polishing the second non-conductive material to the second height using a chemical mechanical polishing (CMP) process, and removing using a photo lithography process and an etching process, the second non-conductive material covering the middle part.

With reference to the second aspect, or the first possible implementation of the second aspect, in a second possible implementation, the second non-conductive material includes silicon oxide. Compared with an organic material such as polyimide, using the silicon oxide to fabricate the flat layer can lead to higher smoothness precision in order to further reduce a risk that the under bump metallization layer and the rewiring layer covering the under bump metallization layer distort, fracture, and peel off. This helps improve a yield rate and reliability of a plurality of rewiring layers. In addition, the rewiring layer becomes more even because of improvement in flatness, and signals transmitted using the rewiring layer are also more consistent.

With reference to any one of the second aspect, or the first and the second possible implementations of the second aspect, in a third possible implementation, the silicon oxide includes silicon dioxide.

With reference to any one of the second aspect, or the first to the third possible implementations of the second aspect, in a fourth possible implementation, the first non-conductive material includes silicon nitride.

With reference to any one of the second aspect, or the first to the fourth possible implementations of the second aspect, in a fifth possible implementation, the first metallic material includes at least one of copper, nickel, silver, or tin.

With reference to any one of the second aspect, or the first to the fifth possible implementations of the second aspect, in a sixth possible implementation, the second metallic material includes at least one of copper or aluminum.

### BRIEF DESCRIPTION OF DRAWINGS

To describe the technical solutions in some embodiments of the present disclosure more clearly, the following briefly describes the accompanying drawings describing some of the embodiments. The accompanying drawings in the following description show merely some embodiments of the present disclosure, and a person of ordinary skill in the art may still derive other drawings from these accompanying drawings without creative efforts.

FIG. 1 is a sectional schematic diagram of a package structure according to a first embodiment of the present disclosure;

FIG. 2 is a sectional schematic diagram of a semiconductor component, a connection pad, and a protective layer that are in FIG. 1;

FIG. 3 is a flowchart of a package structure fabricating method according to a second embodiment of the present disclosure;

FIG. 4 is a sectional schematic diagram of a structure in a fabricating process in FIG. 3;

FIG. 5 is another sectional schematic diagram of a structure in a fabricating process in FIG. 3; and

FIG. 6 is still another sectional schematic diagram of a structure in a fabricating process in FIG. 3.

### DESCRIPTION OF EMBODIMENTS

The following clearly describes the technical solutions in embodiments of the present disclosure with reference to the accompanying drawings in the embodiments of the present disclosure. The described embodiments are merely some but not all of the embodiments of the present disclosure. All other embodiments obtained by a person of ordinary skill in the art based on the embodiments of the present disclosure without creative efforts shall fall within the protection scope of the present disclosure.

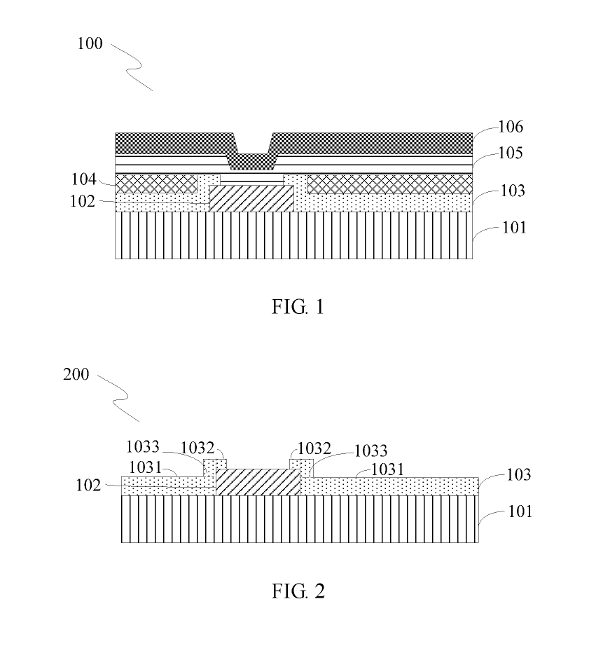

FIG. 1 is a sectional schematic diagram of a package structure 100 according to a first embodiment of the present disclosure. The package structure 100 includes a semiconductor component 101, a connection pad 102, a protective layer 103, a flat layer 104, an under bump metallization layer 105, and a rewiring layer 106.

In an embodiment, the semiconductor component 101 includes a wafer. The connection pad 102 is disposed on the semiconductor component 101. The protective layer 103 includes a first non-conductive material. As shown by a package structure 200 in FIG. 2, the protective layer 103 includes a first part 1031 and a second part 1032. The first part 1031 covers the semiconductor component 101. A surface of the first part 1031 is at a first height. The second part 1032 covers a periphery of the connection pad 102 and is configured to ensure that the protective layer 103 covers all parts of the semiconductor component 101 except an area on which the connection pad 102 is disposed. In an embodiment, from a top view, a surface of the connection pad 102 is in a circular shape. The periphery is an outermost ring of the circular shape. In a process of fabricating a 28-nanometer (nm) semiconductor, a diameter of the connection pad 102 is about 100 micrometer (μm), an outer diameter of the ring is the same as the diameter of the connection pad 102, and an inner diameter of the ring is about 80 μm. A surface of the second part 1032 is at a second height. The first height is less than the second height. A middle part of the connection pad 102 is exposed. The middle part includes a part on the connection pad 102 except the periphery. In the process of fabricating a 28-nm semiconductor, from a top view, a diameter of the middle part is the same as the inner diameter of the ring. The first part 1031 and the second part 1032 are connected at an edge 1033 of the connection pad 102. In an embodiment, the first non-conductive material includes silicon nitride.

The flat layer 104 includes a second non-conductive material and covers the first part 1031. A surface of the flat layer 104 is at the second height such that the surface of the flat layer 104 is flush with the surface of the second part 1032. The flat layer 104 makes up a height difference between the first part 1031 and the second part 1032 of the protective layer 103 such that the under bump metallization layer 105 can cover a smoother surface, and a risk that the under bump metallization layer 105 and the rewiring layer 106 covering the under bump metallization layer 105 distort, fracture, and peel off at an unsmooth part is reduced. In an embodiment, the second non-conductive material includes silicon oxide. For example, the silicon oxide is silicon dioxide. Compared with an organic material such as polyimide, using the silicon oxide to fabricate the flat layer 104 can lead to higher smoothness precision in order to further reduce a risk that the under bump metallization layer 105 and the rewiring layer 106 covering the under bump metallization layer 105 distort, fracture, and peel off. This helps improve a yield rate and reliability of a plurality of rewiring layers. In addition, the rewiring layer 106 becomes more even because of improvement in flatness, and signals transmitted using the rewiring layer 106 are also more consistent.

The under bump metallization layer 105 includes a first metallic material and covers the flat layer 104, the second part 1032, and the middle part of the connection pad 102. The first metallic material includes at least one of copper, nickel, silver, or tin. The rewiring layer 106 includes a second metallic material and covers the under bump metallization layer 105. In an embodiment, the second metallic material includes at least one of copper or aluminum.

The connection pad 102 is configured to connect to the rewiring layer 106 using the under bump metallization layer 105, and the rewiring layer 106 is connected to an electrical conducting wire such that the connection pad 102 is electrically connected to another electrical component. The under bump metallization layer 105 is configured to keep a value of resistance generated between the connection pad 102 and the rewiring layer 106 steady in different conditions (such as different voltage conditions).

In an embodiment, the package structure 100 includes a plurality of structures shown in FIG. 1. A plurality of semiconductor components 101, protective layers 103, flat layers 104, under bump metallization layers 105, and rewiring layers 106 in the structures shown in FIG. 1 are separately connected together. For example, the package structure 100 includes a structure A and a structure B that are shown in FIG. 1. The semiconductor component 101 in the structure A and the semiconductor component 101 in the structure B are connected together, the protective layer 103 in the structure A and the protective layer 103 in the structure B are connected together, and so on.

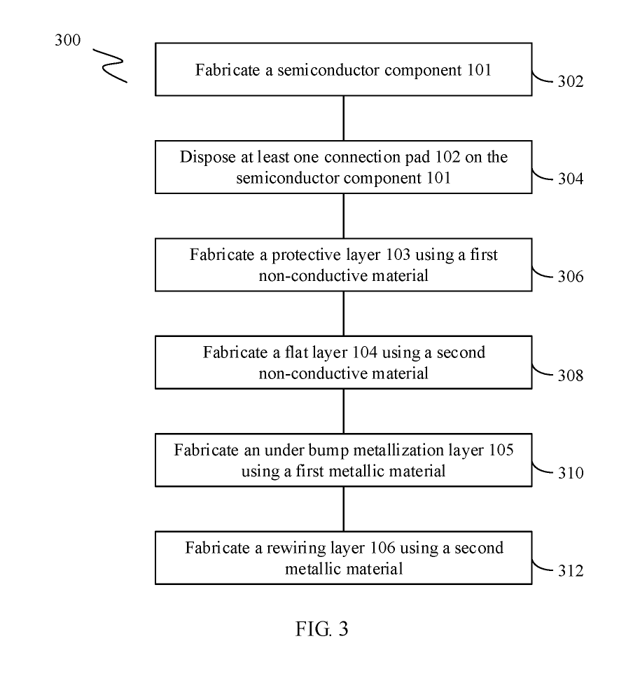

FIG. 3 is a flowchart 300 of a package structure fabricating method according to a second embodiment of the present disclosure. As shown in FIG. 3, in step 302, a semiconductor component 101 is fabricated. In an embodiment, the semiconductor component 101 includes a wafer. In step 304, a connection pad 102 is disposed on the semiconductor component 101. In step 306, a protective layer 103 is fabricated using a first non-conductive material. The protective layer 103 includes a first part 1031 and a second part 1032. The semiconductor component 101 is covered with the first part 1031 such that a surface of the first part 1031 is at a first height. A periphery of the connection pad 102 is covered with a second part 1032 such that a surface of the second part 1032 is at a second height. The first height is less than the second height such that a middle part of the connection pad 102 is exposed. The middle part includes a part on the connection pad 102 except the periphery. The first part 1031 and the second part 1032 are connected at an edge 1033 of the connection pad 102. In an embodiment, the first non-conductive material includes silicon nitride.

In step 308, a flat layer 104 is fabricated using a second non-conductive material. Further, the first part 1031 is covered with the flat layer 104 such that a surface of the flat layer 104 is at the second height. The flat layer 104 makes up a height difference between the first part 1031 and the second part 1032 of the protective layer 103 such that an under bump metallization layer 105 in a subsequent process can cover a smoother surface, and a risk that the under bump metallization layer 105 and a rewiring layer 106 covering the under bump metallization layer 105 distort, fracture, and peel off at an unsmooth part is reduced.

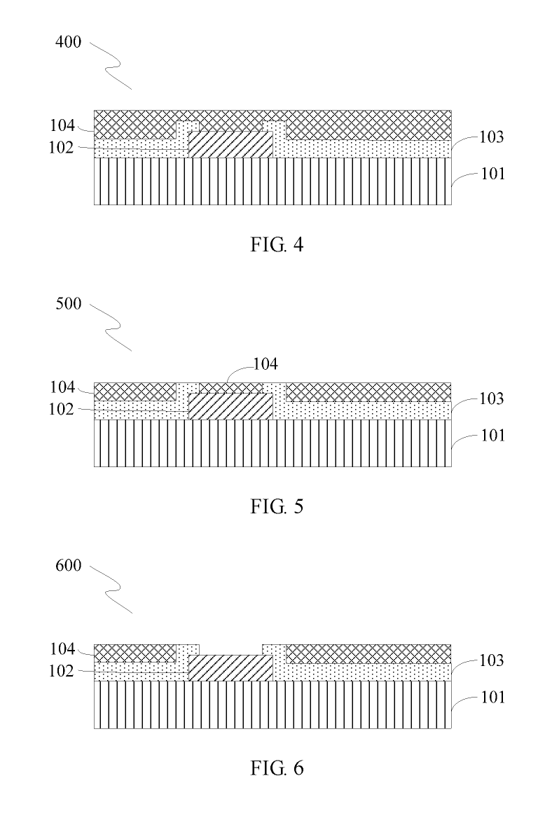

In an embodiment, that the first part 1031 is covered with the flat layer 104 such that a surface of the flat layer 104 is at the second height includes as shown in a package structure 400 of FIG. 4, the protective layer 103 and the middle part of the connection pad 102 are covered with a second non-conductive material using a CVD process, as shown in a package structure 500 of FIG. 5, the second non-conductive material is polished to the second height using a CMP process, and as shown in a package structure 600 of FIG. 6, the second non-conductive material covering the middle part of the connection pad 102 is removed using a photo lithography process and an etching process. In an embodiment, the second non-conductive material includes silicon oxide. For example, the silicon oxide includes silicon dioxide. Compared with an organic material such as polyimide, using the silicon oxide to fabricate the flat layer 104 can lead to higher smoothness precision in order to further reduce a risk that the under bump metallization layer 105 and the rewiring layer 106 covering the under bump metallization layer 105 distort, fracture, and peel off. This helps improve a yield rate and reliability of a plurality of rewiring layers. In addition, the rewiring layer 106 becomes more even because of improvement in flatness, and signals transmitted using the rewiring layer 106 are also more consistent.

In step 310, the under bump metallization layer 105 is fabricated using a first metallic material such that the flat layer 104, the second part 1032, and the middle part of the connection pad 102 are covered with the under bump metallization layer 105. In an embodiment, the first metallic material includes at least one of copper, nickel, silver, or tin. In step 312, the rewiring layer 106 is fabricated using a second metallic material such that the under bump metallization layer 105 is covered with the rewiring layer 106. The second metallic material includes at least one of copper or aluminum.

What is disclosed above is merely examples of the embodiments of the present disclosure, and certainly is not intended to limit the protection scope of the present disclosure. Therefore, equivalent variations made in accordance with the claims of the present disclosure shall fall within the scope of the present disclosure.

What is claimed is:

1. A semiconductor package structure, comprising:
a semiconductor component;
a connection pad disposed on the semiconductor component, wherein a middle part of the connection pad is exposed, and wherein the middle part comprises a part on the connection pad except a periphery;
a protective layer, wherein the protective layer comprises:
a first non-conductive material;
a first part, wherein the first part is configured to cover the semiconductor component except the connection pad, and wherein a surface of the first part is at a first height; and
a second part, wherein the second part is configured to cover the periphery of the connection pad, wherein a surface of the second part is at a second height, wherein the first height is less than the second height, and wherein the first part and the second part are coupled at an edge of the connection pad;
a flat layer, wherein the flat layer comprises a second non-conductive material and is configured to cover the first part, and wherein a surface of the flat layer is at the second height;
an under bump metallization layer, wherein the under bump metallization layer comprises a first metallic material and is configured to cover the flat layer, the second part, and the middle part; and
a rewiring layer, wherein the rewiring layer comprises a second metallic material and is configured to cover the under bump metallization layer.

2. The semiconductor package structure of claim 1, wherein the second non-conductive material comprises silicon oxide.

3. The semiconductor package structure of claim 2, wherein the silicon oxide comprises silicon dioxide.

4. The semiconductor package structure of claim 1, wherein the first non-conductive material comprises silicon nitride.

5. The semiconductor package structure of claim 1, wherein the first metallic material comprises copper.

6. The semiconductor package structure of claim 1, wherein the first metallic material comprises nickel.

7. The semiconductor package structure of claim 1, wherein the first metallic material comprises silver.

8. The semiconductor package structure of claim 1, wherein the first metallic material comprises tin.

9. The semiconductor package structure of claim 1, wherein the second metallic material comprises copper.

10. The semiconductor package structure of claim 1, wherein the second metallic material comprises aluminum.

11. A semiconductor package structure fabricating method, comprising:
fabricating a semiconductor component;
disposing a connection pad on the semiconductor component;
fabricating a protective layer using a first non-conductive material, wherein the protective layer comprises a first part and a second part, and wherein fabricating the protective layer comprises:
covering the semiconductor component except the connection pad with the first part such that a surface of the first part is at a first height;
covering a periphery of the connection pad with the second part such that a surface of the second part is at a second height, wherein the first height is less than the second height; and
exposing a middle part of the connection pad, wherein the middle part comprises a part on the connection pad except the periphery, and wherein the first part and the second part are coupled at an edge of the connection pad;
fabricating a flat layer using a second non-conductive material, wherein fabricating the flat layer comprises covering the first part with the flat layer such that a surface of the flat layer is at the second height;
fabricating an under bump metallization layer using a first metallic material;
covering the flat layer, the second part, and the middle part with the under bump metallization layer;
fabricating a rewiring layer using a second metallic material; and
covering the under bump metallization layer with the rewiring layer.

12. The semiconductor package structure fabricating method of claim 11, wherein covering the first part with the flat layer comprises:
covering the protective layer and the middle part with the second non-conductive material using a chemical vapor deposition (CVD) process;
polishing the second non-conductive material to the second height using a chemical mechanical polishing (CMP) process; and
removing, using a photo lithography process and an etching process, the second non-conductive material covering the middle part.

13. The semiconductor package structure fabricating method of claim 11, wherein the second non-conductive material comprises silicon oxide.

14. The semiconductor package structure fabricating method of claim 13, wherein the silicon oxide comprises silicon dioxide.

15. The semiconductor package structure fabricating method of claim 11, wherein the first non-conductive material comprises silicon nitride.

16. The semiconductor package structure fabricating method of claim 11, wherein the first metallic material comprises copper.

17. The semiconductor package structure fabricating method of claim 11, wherein the first metallic material comprises nickel.

18. The semiconductor package structure fabricating method of claim 11, wherein the first metallic material comprises silver.

19. The semiconductor package structure fabricating method of claim 11, wherein the first metallic material comprises tin.

20. The semiconductor package structure fabricating method of claim 11, wherein the second metallic material comprises at least one of copper or a
